(19) United States
(12) Patent Application Publication
(10) Pub. No.: US 2009/0078601 A1
(43) Pub. Date: Mar. 26, 2009

(54) CONTAINER FOR DISK DRIVERS

(75) Inventors: YOUG-SIANG LIN, Guishan Shiang (TW); Jen-Chen Wu, Guishan Shiang (TW)

Correspondence Address: G. LINK CO., LTD., 3550 BELL ROAD, MINOOKA, IL, 60447, US

(73) Assignee: QUANTA STORAGE INC., Guishan Shiang (TW)

(21) Appl. No.: 12/108,080

(22) Filed: Apr. 23, 2008

(30) Foreign Application Priority Data
Sep. 21, 2007 (TW) 096135829

(51) Int. Cl. B65D 85/32; H05K 5/00; B65D 85/86

(52) U.S. Cl. 206/307; 206/308.1

(57) ABSTRACT

The invention provides a container for packaging disk drives comprising a lower cover and an upper cover. The lower cover is a thick, flat buffer having a rectangular carrier recess concavely disposed at the center of its top surface. The carrier recess is divided into a plurality of partition spaces by criss-crossing flat partition board. The lower end of the partition board is inserted into the carrier recess. An indent is disposed at the top end of each partition spaces. A plurality of vertical wings protrude from the center of each side of the partition board where the lower end of the wings sits on the edge of carrier recess of lower cover. The upper cover is a thick, flat buffer having a rectangular carrier recess concavely disposed at the center of its bottom surface. The carrier recess of the upper cover can cover the top end of partition board such that its edge can sit on the upper end of the wings to load more disk drives.

### FIELD OF THE INVENTION

The present invention relates to a container, more particularly a container for packaging disk drives during handling and shipment for shock insulation and easy pick and place.

### BACKGROUND OF THE INVENTION

Disk drive is used to read and write high-density data. Its internal components are particularly small and delicate. Thus the storage container for housing disk drives must have shock resistance to protect the disk drives from shock during handling and shipment that might cause displacement of components to affect the accuracy of data reading and writing.

As shown in FIG. 1, a conventional container 1 for disk drives comprise a upper cover 2 and a lower cover 3, each having respectively a plurality of symmetrical upper recesses 4 and lower recesses 5. The space formed by the opposing upper recess 4 and lower recess 5 can fittingly accommodate the disk drive 6. For shock insulation, container 1 is typically molded with material with certain elasticity, such as pulp or Styrofoam. But such material lacks sufficient structural strength so that the partition blocks 7 between the recesses must have adequate size and thickness to add to the structural strength and shock insulation capability of the container. In addition, during the molding of the container 1, the side walls 8 of the upper recesses 4 and lower recesses 5 are typically set with a 2-3 degree gradient to facilitate mold release. When preparing the disk drives 6 for shipment, disk drives 6 are inserted one by one into the lower recesses 5 of the lower cover 3 until full, and the upper cover 2 is then placed over the lower cover 3. The set of upper cover 2 and lower cover 3 is placed into the carton box to complete the packaging of disk drives 6.

Given the gradient on the side walls 8 of container 1, the disk drives 6 placed in the container 1 would naturally lean obliquely against the side wall 8 (as shown by dotted line) towards left or right. As such, the top edge of the disk drives 6 is unable to align squarely with the upper recess 4 that the slanted disk drives 6 must be put straight one by one in order to close the upper cover 2, which adds to the work of packaging. In addition, the use of oversized or very thick partition blocks 7 to increase structural strength cuts down the number of disk drives, and a standard-size container can hold to approximately 15-20, which tends to increase shipping cost, storage space and expenses. If a container is too big, it will take a lot of space for storage, and create more challenges in its fabrication and handling. Thus the space layout of conventional container for disk drives has room for improvement.

### SUMMARY OF THE INVENTION

The primary object of the invention is to provide a container for disk drives using a partition board for packaging disk drives to increase the quantity of disk drives that can be held so as to reduce the shipping costs and storage space effectively.

Another object of the invention is to provide a container for disk drives using a partition board together with buffer materials for packaging disk drives to render the pick and place of disk drives easier and to enhance their handling efficiency.

Yet another object of the invention is to provide a container for disk drives using a partition board for packaging disk drives. The partition board can be laid flat for storage to decrease the use of buffer material and reduce the space required for storing empty container and storage expenses.

A further object of the invention is to provide a container for disk drives that has a spring-action member in each partition space divided by the partition board to prevent the wiggling of disk drives during shipment, hence producing better shock insulation effect.

Yet another object of the invention is to provide a container for disk drives that places a fool-proof member on the partition board to orient the insertion of disk drives into the carrier recess to render the placement of disk drives consistent and facilitate their take-out for assembly.

To achieve the aforesaid objects, the invention provides a container for disk drives comprising a lower cover and an upper cover. The lower cover is a thick, flat buffer having a rectangular carrier recess concavely disposed at the center of its top surface. The carrier recess is divided into a plurality of partition spaces by crisscrossing partition board made of buffer material. The lower end of the partition board is inserted into the carrier recess. An indent is disposed at the top end of each partition spaces. A plurality of vertical wings protrude from the center of each side of the partition board where the lower end of the wings sits on the edge of carrier recess of lower cover. The upper cover is a thick, flat buffer having a rectangular carrier recess concavely disposed at the center of its bottom surface. The carrier recess of the upper cover can cover the top end of partition board such that its edge can sit on the upper end of the wings.

The partition board contains a plurality of main beards and a plurality of auxiliary boards. The main boards are arranged in parallel to form a plurality of storage units separated by a center slit. A wing protrudes from each lateral sides of the main board that is separated from the storage unit by a side slit. An indent is concavely disposed at the center of the upper end of the storage unit. The auxiliary board has a shield body with a wing protruding from each end that is separated from the shield body by an auxiliary slit. A plurality of auxiliary slits are disposed between the two auxiliary slits separating the wings from the shield body. The two auxiliary boards are cross-slotted into the side slits of each main board via the auxiliary slits, while the other auxiliary board is cross-slotted into the center slit of each main board via the auxiliary slits to form a partition board.

A part of main board on each side of the indent is bent down inwardly toward the partition space to form a spring-action member. The distance of downward bend is one half the depth of indent. The spring-action member can also be formed by bending downward from the bottom of indent the material cut off in the formation of indent. The spring-action member is for preventing the wiggling of disk drives during shipment to enhance the shock insulation effect. In addition, a hole is drilled at one side near the bottom of the main board, which, with an orientation lever made of buffer material passing through, can orient the insertion of disk drives into the carrier recess.

### BRIEF DESCRIPTION OF THE DRAWINGS

FIG. 1 is a sectional view of a conventional container for disk drives;

FIG. 2 is a perspective view of the container for disk drives according to the first embodiment of the invention;

FIG. 3 is an exploded view of the partition board according to the first embodiment of the invention;

FIG. 4 is a perspective assembly view of the container for disk drives according to the first embodiment of the invention:

FIG. 5 is a perspective view of the container for disk drives according to the second embodiment of the invention;

FIG. 6 is a side sectional view of the partition board according to the second embodiment of the invention;

FIG. 7 is a perspective view of the partition board according to the third embodiment of the invention;

FIG. 8 is a side sectional view of the partition board according to the third embodiment of the invention; and

FIG. 9 is a perspective view of the partition board according to the fourth embodiment of the invention.

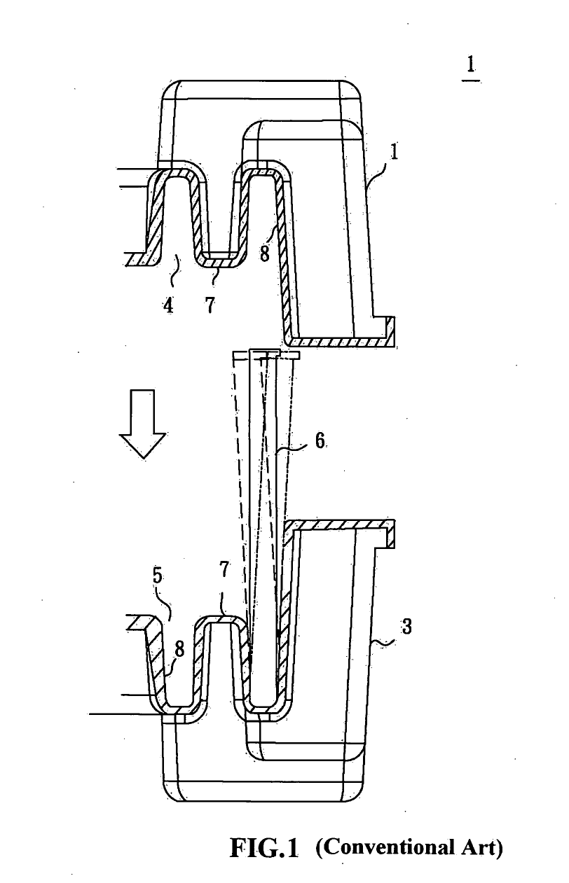

### DETAILED DESCRIPTION OF THE INVENTION

To achieve the aforesaid objects, the techniques, means and effects of the invention are described in detail below with embodiments in reference to the accompanying drawings.

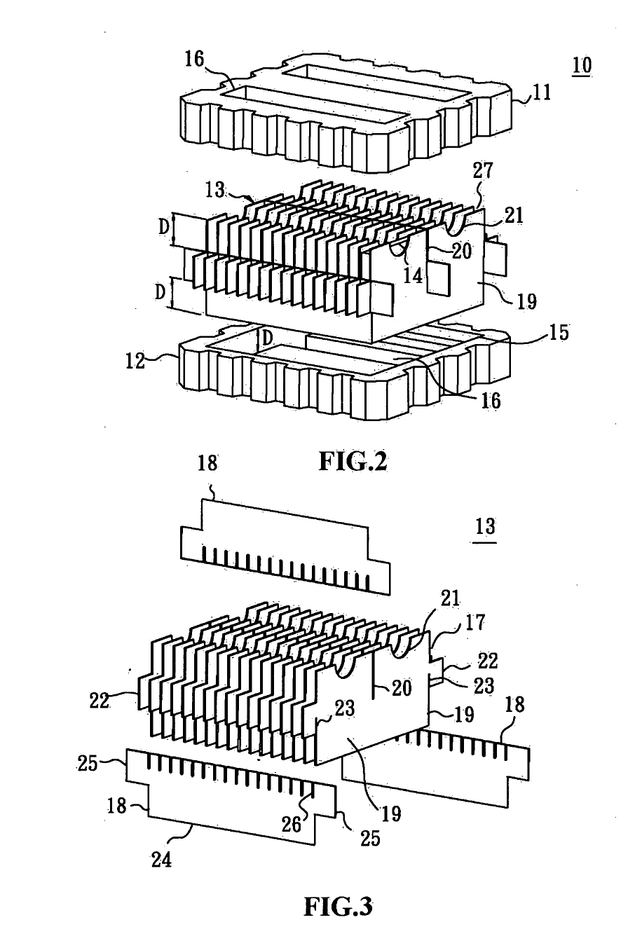

Referring to FIG. 2, the container for disk drives 10 in the first embodiment of the invention comprises an upper cover 11, a lower cover 12 and a partition board 13, wherein the partition board 13 is placed over the lower cover 12, and the upper cover 11 overlies the partition board 13 after the disk drives 14 are loaded to complete the packaging of disk drives.

The upper cover 11 and the lower cover 12 are molded with buffer material, such as foam, Styrofoam or pulp, and have roughly the same shape. In the example of lower cover 12, lower cover 12 is a flat buffer with proper thickness having a rectangular carrier recess 15 concavely disposed at the center of top surface. The carrier recess 15 has a depth D and is inwardly disposed with two long holes 16 to obtain a concave-convex form at the periphery so as to reduce the use of buffer material, thereby lowering the material cost. If the lower cover 12 is rotated 180 degrees with the carrier recess 15 facing downward, the lower cover 12 becomes upper cover 11. Thus the upper cover 11 and the lower cover 12 of the invention may be used interchangeably to cut down the manufacturing costs and add to the convenience of usage.

FIG. 3 is an exploded view of partition board 13. Referring to FIG. 2 and FIG. 3, the partition board 13 is basically a flat board made of, for example, corrugated paper and comprises a plurality of main boards 17 and three auxiliary boards 18. Each main board 17 is basically a rectangular flat board. The main boards 17 are arranged in parallel according to the size of the disk drive 14 to form a plurality of storage units 19. This embodiment has two storage units 19 which are separated by a center slit 20. The center slit 20 has a length approximately half the height of main board 17 instead of traversing the entire main board 17 such that the storage units 19 are connected together. A semi-circular indent 21 is disposed at the top center of each storage unit 19. The depth of indent 21 is less than the height of the disk drive 14 such that the upper end of the disk drive 14 is exposed after it is placed in the storage unit 19 formed by partition board 13 to facilitate its take-out. In the middle of two sides of the main board 17 which are the sides of the two outermost storage units 19, there is protrudingly disposed respectively a rectangular wing 22 with proper height. The wings 22 are separated from the storage units 19 by a side silt 23. The length of side silt 23 is approximately half the height of the wing 22 instead of traversing the entire wing 22 such that the wing 22 and the storage unit 19 can remain connected. After subtracting the height of the wing 22 from the height of two sides of the main board 17, the upper part and lower part of the side of the main board 17 will each have a height equal to the depth D of the carrier recess 15.

The auxiliary board 18 is basically a flat board having a rectangular shield body 24 and protrudingly disposed with a wing 25 on the right and the left side. The wing 25 has the same shape and height as the wing 22 of main board 17 and is separated from the shield body 24 by an auxiliary slit 26 at the top. The length of auxiliary slit 26 is approximately half the height of wing 25 instead of traversing the entire wing 25 such that the wing 25 and the shield body 24 remain connected. At the top end of the shield body 24 between two auxiliary slits 26 on the side, a plurality of auxiliary slits 26 are arranged at the predetermined distance apart.

In the assembly of partition board 13, two auxiliary boards 18 are secured to the main board 17 by having their auxiliary slit 26 on one side cross embedding into the side slit 23 on each side of main board 17, and then the other side slits 23 of the main board 17 are cross embedded into the other auxiliary slits 26 of the auxiliary boards 18. Finally invert the third auxiliary board 18 such that its auxiliary slit 26 faces down and cross embeds into the center slit 20 of main board 17. The front and back of main boards 17 and the auxiliary boards 18 sitting in side slits 23 and center slits 20 form a plurality of partition spaces 27 for the placement of disk drives 14. Given that the main boards 17 and the auxiliary boards 18 are flat buffers, they can compartmentize about 30 partition spaces 27 of equal size.

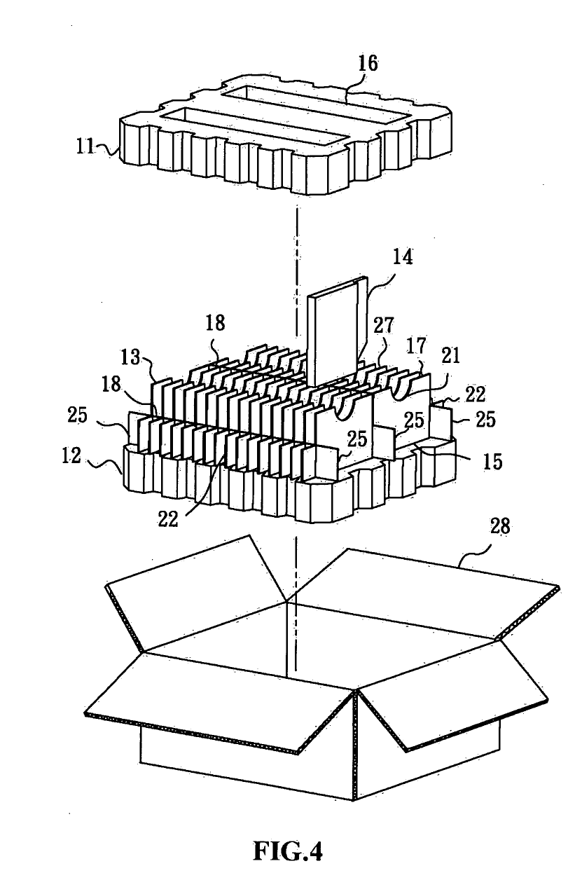

As shown in FIG. 4, when the container for disk drives in the first embodiment is in used, place the lower cover 12 beneath the end of partition board 13 without the indent 21 to let the lower end of partition board 13 enter the carrier recess 15. Because the height of the partition board 13 and the depth of the carrier recess 15 are both D, the lower ends of the wings 22 protruding from the main boards 17 and the wings 25 of the auxiliary boards 18 would sit on the edge of carrier recess 15. Then antistatic foam-packed disk drives 14 are loaded one by one into the partition spaces 27 such that the bottom of each disk drive 14 is supported by the carrier recess 15 and stretches securely across the long hole 16 that has less width without falling. The periphery of the disk drive 14 is protected by the buffer material of main board 17 and three auxiliary boards 18. The disk drive 14 is positioned slightly lower than the partition space 27. Because the upper cover 11 contains only a carrier recess 15, it can easily lay over as long as the carrier recess 15 holds the top end of partition board 13. Similarly because the height of the partition board 13 and the depth of the carrier recess 15 are both D, the upper ends of the wings 22 protruding from the main boards 17 and the wings 25 of the auxiliary boards 18 would contact the edge of carrier recess 15 of upper cover 11. As wings 22 and wings 25 stand upright between the edges of upper cover 11 and lower cover 12 to withstand the force pressing against the upper cover 11 and the lower cover 12, no force is exerted directly on the disk drives 14 therein. Finally, put the assembled upper cover 11, partition board 13 and lower cover 12 into the carton box 28 to finish the packaging.

The container for disk drives according to the first embodiment of the invention can hold ⅓ to ½ more disk drives by using thinner partition board for packaging, which could help reduce shipping charges and storage space. The partition board 13 in an empty container can be pressed flat for storage, which not only cuts down the use of fixed-volume buffer material, but also reduces the storage space and expenses. In addition, the upper cover with only a carrier recess can be put in place without straightening up the disk drives one by one, hence facilitating the packaging of disk drives for shipment.

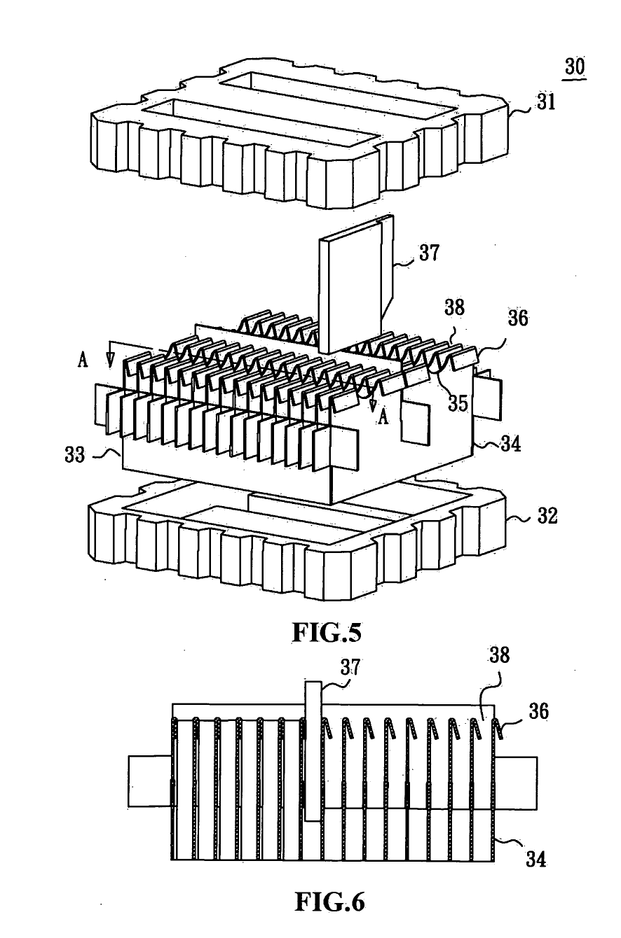

FIG. 5 shows a container 30 for disk drives in the second embodiment of the invention. The container 30 comprising an upper cover 31, a lower cover 32 and a partition board 33 has basically the same spatial structure as the container for disk drives in the first embodiment. The difference lies in the partition board 33 where the top end of each main board 34 on either side of the indent 25 is bent downward to form a bent spring-action member 36. The bend distance of the spring-action member 36 is approximately half the depth of indent 35 so that the disk drives 37 when placed in would still be lower than the height of partition space 38. The bent spring-action member 36 is obliquely extended in the partition space 38. As shown in FIG. 6 which is a side sectional view along the midline A-A in FIG. 5, for shipment, the disk drive 37 is inserted into the partition space 38 and presses against the spring-action member 36 along the direction of its bend to push the spring-action member 36 towards the main board 34. After the disk drive 37 goes into the partition space 38, the spring-action member 36 would hold the top end of the disk drive 37 with its rebound force to keep the disk drive 37 from moving in the partition space 38. The buffer material of the spring-action member 36 also provides shock insulation effect for the disk drive 37 during shipment.

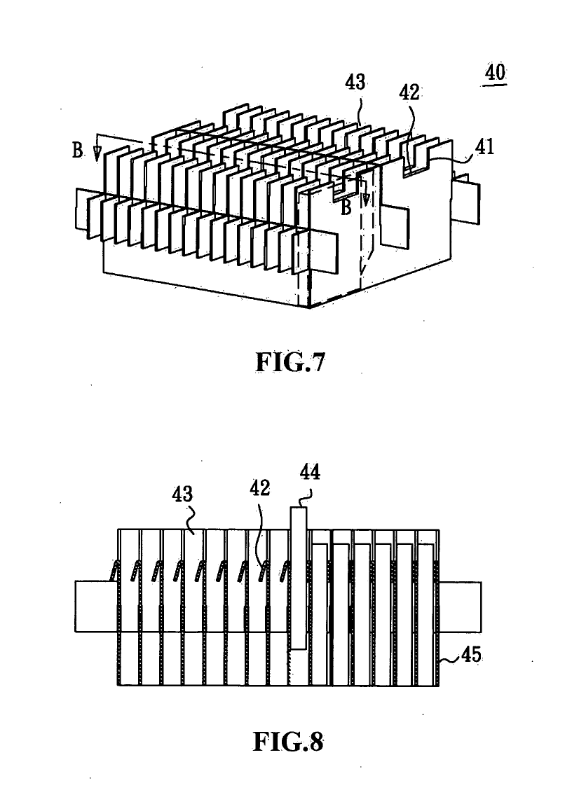

FIG. 7 shows a container for disk drives according to a third embodiment of the invention, which also has essentially the same spatial structure as the container in the first embodiment. The difference is that the indent 41 of the partition board 40 has a rectangular shape. When cutting the indent 41, the off-cut material is left connected at the base of indent 41 and bent downward into a bent spring-action member 42 to reduce scraps. The bent spring-action member 42 is obliquely extended in the partition space 43. As shown in FIG. 8 which is a side sectional view along the midline B-B in FIG. 7, for shipment, the disk drive 44 is inserted into the partition space 43 and presses against the spring-action member 42 along the direction of its bend to push the spring-action member 42 towards the main board 45. After the disk drive 44 goes into the partition space 43, the spring-action member 42 would hold the disk drive 44 at a spot close to the center of disk drive 44 with its rebound force to limit the movement of disk drive 44 in the partition space 43 even better than the case in the second embodiment. The buffer material of the spring-action member 42 also provides shock insulation effect for the disk drive 44 during shipment. The spring-action member 42 in this embodiment can exist simultaneously with the spring-action member in the second embodiment to provide even better shock insulation for disk drives during shipment.

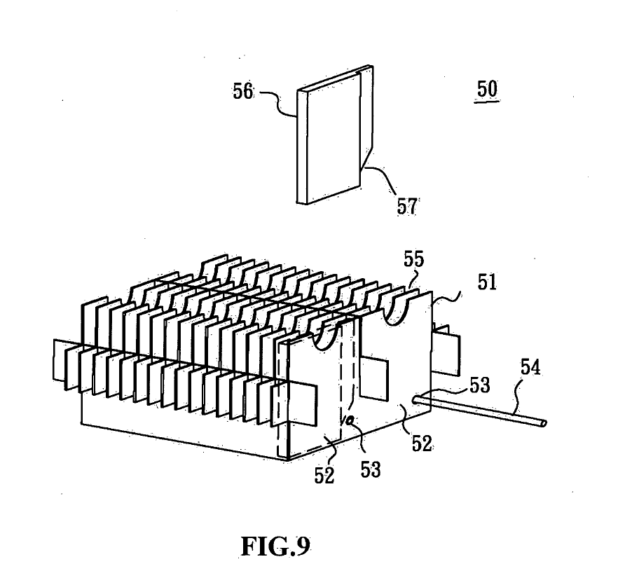

FIG. 9 shows a container for disk drives according to a fourth embodiment of the invention, which also has essentially the same spatial structure as the container in the first embodiment. The difference is that a through-hole 53 is drilled through a lower side of each storage unit 52 formed by the main boards 51 of the partition board 50 in line with the placement direction of the disk drive 56. In this embodiment, a through-hole 53 is drilled at the lower right side of storage units 52. When the partition board 50 is assembled, the through-holes 53 of tandemly arranged storage units 52 are lined up in a row. An orientation lever 54 served as a fool-proof member is inserted into the through-holes 53 of storage units 52 and horizontally secured in each partition space 55. The orientation lever 54 can be made of buffer material. When the disk drive placed into the partition space 55 is a thin type of disk drive 56 that comes with a notch 57, the orientation lever 54 will be located at exactly where the notch 57 is without affecting the placement of disk drive 56 if it is inserted correctly. Conversely, if the thin disk drive 56 is not inserted correctly, the orientation lever 54 will not align with the side of notch 57 and will interfere with the placement of disk drives 56 into the partition spaces 55, hence requiring adjustment. As such, all disk drives 56 loaded in the container will have the same orientation to facilitate assembly at the production line.

The examples cited above are meant to explain the invention and should not be construed as a limitation on the actual applicable scope of the invention, and as such, all modifications and alterations without departing from the spirits of the invention and appended claims shall remain within the protected scope and claims of the invention.

What is claimed is:

1. A container for disk drives, comprising:
a lower cover being a thick, flat buffer having a rectangular carrier recess concavely disposed at the center of its top surface;
a partition board being crisscrossing flat boards made of buffer material to enclose a plurality of partition spaces, the carrier recess of the lower cover being able to accommodate the lower end of partition board, each partition space having an indent at the top and a plurality of vertical wings protruding from the center of each side, the lower end of the wings sitting on the edge of carrier recess; and
an upper cover being a thick, flat buffer having a rectangular carrier recess concavely disposed at the center of its bottom surface, the carrier recess being able to cover the top end of partition board such that its edge can sit on the upper end of the wings.

2. The container for disk drives according to claim 1, wherein the upper cover and the lower cover have identical shape.

3. The container for disk drives according to claim 1, wherein the portions of the side of partition board above and below the wing have a height equal to the depth of the carrier recess.

4. The container for disk drives according to claim 1, wherein the partition board contains a plurality of main boards and a plurality of auxiliary boards, the main boards being arranged in parallel to form a plurality of storage units separated by a center slit, the main boards having a wing protruding from each lateral sides and being separated from the storage unit by a side slit, the auxiliary board having a shield body with a wing protruding from each end that is separated from the shield body by an auxiliary slit, a plurality of auxiliary slits being disposed between the two auxiliary slits separating the wings from the shield body, the two auxiliary boards being cross-slotted into the side slits of each main board via the auxiliary slits, while the other auxiliary board being cross-slotted into the center slit of each main board via the auxiliary slits.

5. The container for disk drives according to claim 4, wherein the storage unit has an indent concavely disposed at the center of its top end.

6. The container for disk drives according to claim 1, wherein the partition board is bent down inwardly toward the partition space to form a spring-action member.

7. The container for disk drives according to claim 6, wherein the spring-action member is situated on each side of indent.

8. The container for disk drives according to claim 7, wherein the spring-action member is bent down from the top end of the portion of partition board on each side of the indent, the bend distance being half of the depth of indent.

9. The container for disk drives according to claim 6, wherein the spring-action member is situated beneath the indent.

10. The container for disk drives according to claim 9, wherein the spring-action member is made of off-cut material used in the making of indent.

11. The container for disk drives according to claim 9, wherein the indent has a rectangular shape.

12. The container for disk drives according to claim 1, wherein the partition board is disposed with a through-hole at a lower side of the partition space that allows the pass-through of an orientation lever made of buffer material.

13. The container for disk drives according to claim 1, wherein the disk drives are packed in anti-static foam bag.
